(19) United States
(12) Patent Application Publication
(10) Pub. No.: US 2006/0192085 A1
(43) Pub. Date: Aug. 31, 2006

(54) Semiconductor circuit and arrangement and method for monitoring fuses of a semiconductor circuit

(76) Inventors: Georg Erhard Eggers, Muenchen (DE); Manfred Proell, Dorfen (DE); Joerg Kliewer, Muenchen (DE); Stephan Schroeder, Muenchen (DE)

Correspondence Address: SLATER & MATSIL LLP, 17950 PRESTON ROAD, SUITE 1000, DALLAS, TX, 75252, US

(21) Appl. No.: 11/341,904

(22) Filed: Jan. 27, 2006

(30) Foreign Application Priority Data
Jan. 28, 2005 (DE) 10 2005 004 108.6

(51) Int. Cl. H01L 31/00

(52) U.S. Cl. 250/214.1

(57) ABSTRACT

A semiconductor circuit comprises a fuse and a photoelement. A conduction layer of the fuse at least partly shades a photosensor region of the photoelement from a light bundle falling onto the semiconductor circuit. An arrangement for electro-optical monitoring of fuses of a semiconductor circuit additionally comprises an illumination device for generating the light bundle and a measuring device connected to two of the terminal contacts of the semiconductor circuit. In a method for the electro-optical monitoring of fuses of a semiconductor circuit a measuring device is connected to two of the terminal contacts and the semiconductor circuit is illuminated with a light bundle.

This application claims priority to German Patent Application 10 2005 004 108.6, which was filed Jan. 28, 2005, and which is incorporated herein by reference.

### TECHNICAL FIELD

The invention relates to a semiconductor circuit having fuses that can be programmed by a laser beam or by impressing energy. Moreover, the invention relates to an arrangement and a method for monitoring fuses.

### BACKGROUND

A dynamic semiconductor memory contains an array of memory cells for storing information and support circuits for accessing the stored information by means of memory addresses. Information stored in a memory cell is represented by the charge of a capacitor. The charge has to be refreshed at regular time intervals in order to counteract a dissipation of the charge on account of leakage currents and, thus, a loss of the information. The support circuits within the dynamic semiconductor memory contain, inter alia, voltage generators for generating a plurality of internal voltage levels.

If a semiconductor memory is tested after production, values that fluctuate within certain expected production tolerances then result for the internal voltage levels. Moreover, some of the memory cells may be defective.

In order to ensure proper operation of the semiconductor memory, the internal voltage levels are intended to have previously defined values, however. Moreover, the intention is for none of the memory addresses to permit access to a defective memory cell. Therefore, a modern semiconductor memory is embodied in a programmable fashion. In the case of a programmable semiconductor memory, the internal voltage levels and the assignment between memory addresses and memory cells can be defined after production by programming memory elements. Each of the memory elements can permanently store one bit of information without a supply voltage having to be applied. These memory elements are nonvolatile storage elements.

The memory elements are usually embodied as fuses, which can be programmed by impressing energy, for example, by irradiation with laser light. A fuse contains a metal bridge that produces a conductive connection between two terminals. A resistance value of the fuse is defined by way of the arrangement and the resistivity of the metal bridge. A fuse that has the defined resistance value is unprogrammed. The conductive connection can be interrupted by irradiating the metal bridge with suitably focused laser light for a short period of time. A fuse in which the conductive connection is interrupted is programmed.

After a supply voltage has been applied to the semiconductor memory, the state of all the fuses are read by the support circuits. In this case, each fuse is respectively assigned a latch having an output. Depending on whether or not a fuse is programmed, a voltage level having one of two values is generated at the output of the assigned latch.

If, in the course of impressing energy, the laser beam is not directed correctly or is inadequately focused onto the metal bridge of a fuse, there is the possibility that although a part of the metal bridge is removed, the conductive connection between the two terminals is not interrupted. The fuse is, therefore, not programmed after energy has been impressed. However, after energy has been impressed, the fuse has a resistance value that is higher than the defined resistance value. Therefore, the fuse is neither programmed nor unprogrammed after energy has been impressed. A fuse in which the conductive connection between the two terminals is not interrupted but the resistance value is higher than the defined resistance value is incorrectly programmed. The resistance value may also be increased on account of an oxidation of the metal bridge.

In accordance with the above explanations a fuse is always unprogrammed, programmed, or incorrectly programmed. The fuse is, therefore, assigned a programming state, which always has one of three values. The values of the programming states of all the fuses of a semiconductor memory are referred to hereinafter, for short, as the programming state of the semiconductor memory. The term “programming” hereinafter denotes the operation in which an unprogrammed fuse is converted into either programmed or an incorrectly programmed fuse.

The increased resistance of an incorrectly programmed fuse may have the effect that the voltage level at the output of the assigned latch is set to the incorrect value, or a random value, after application of the supply voltage. Random values of the voltage level may be brought about, for example, by noise of the supply voltage V_{CC}, or by changes in operating temperature.

A random value of the voltage level is particularly critical when depending on the value of the voltage level, a memory address is first assigned to a first memory cell and then to a second memory cell. In this case, a functional test in which first a writing access and then a reading access are affected twice in succession via the same memory address can fail, even though no memory cell of the array is defective.

Thus, there is a long felt need for a circuit and method and arrangement of detecting the programming state of the semiconductor memory. The embodiments of the present invention described below address this need.

### SUMMARY OF THE INVENTION

Consequently, embodiments of the invention provide an arrangement for reliably identifying an incorrectly programmed fuse. Furthermore, embodiments of the invention enable reliably identifying incorrectly programmed fuses in a semiconductor circuit.

According to one preferred embodiment of the invention, advantages are achieved by use of a semiconductor circuit having a fuse element having a first and a second terminal and a conductive layer that is opaque to a light bundle and that can be fused by the impression of a light bundle; and a photoelement having a first and a second terminal and a photosensor that is sensitive to the light bundle; wherein the conductive layer is arranged over the photosensor of the photoelement. In another preferred embodiment, an arrangement and a method for the electro-optical monitoring of fuses of a semiconductor circuit is provided comprising a semiconductor circuit including fuse elements that can be fused by the impression of a light bundle; illumination device for generating a light bundle onto the semiconductor circuit, and a measuring device having the terminals for measuring either current or voltage.

In a preferred method, the fuses of a semiconductor circuit are monitored by providing photoelements with photosensors with the conductive layer of the fuse partially overlying the photoelements, illuminating the fuses with a light bundle and determining a current flowing through a series circuit of a fuse and a photoelement. A semiconductor circuit according to a first preferred embodiment comprises a fuse having a first terminal, a second terminal and a fusible conduction layer, which is opaque to a light bundle. The semiconductor circuit at this embodiment additionally comprises a photoelement having a first terminal, a second terminal and a photosensor region having light-dependent conductivity. The conduction layer is arranged particularly overlaying the photosensor region of the photoelement. The conduction layer produces a conductive connection between the first terminal and the second terminal of the fuse. The photosensor region has a light-dependent conductivity. If light can enter into the photosensor region, then, a conductive connection is produced between the first terminal and the second terminal of the photoelement. The photoelement is, therefore, a switch having a current path that can be controlled by light radiating in. If the fuse is unprogrammed, the photosensor region of the photoelement is completely covered by the metal bridge of the fuse. In this case, no light can enter into the photosensor region and no appreciable current can flow through the photoelement. If the fuse is programmed, then the conductive connection between the first terminal and the second terminal of the fuse is completely interrupted. In this case, no current can flow through the fuse. In contrast, if the fuse is incorrectly programmed, the electrical connection between the first terminal and the second terminal of the fuse is not interrupted. Therefore, a current can flow through the fuse. At the same time, if the fuse is incorrectly programmed, a part of the metal bridge of the fuse is removed and a part of the photosensor region arranged below the metal bridge is uncovered, whereby light enters into the photosensor region. Therefore, a current can flow through the photoelement. When a fuse is unprogrammed, no current can flow through the photoelement; but when a fuse is programmed, no current can flow through the fuse; when a fuse is incorrectly programmed, a current can flow both through the photoelement and through the fuse. Thus, there are three possible outcomes of programming for a fuse that can now be determined.

The second terminal of the photoelement and the first terminal of the fuse are preferably electrically conductively connected to one another. The semiconductor circuit then contains a series circuit comprising the photoelement and the fuse.

A current can flow through the series circuit only if the current can flow through the fuse and the photoelement. Therefore, a current can flow through the series circuit only if the fuse is incorrectly programmed. No appreciable current can flow through the series circuit when the fuse is unprogrammed, or, when the fuse is correctly programmed.

The series circuit has a high resistance value if the conduction layer of the fuse completely covers the photosensor region of the photoelement. The fuse is unprogrammed in this case. No light can enter into the photosensor region and, consequently, no appreciable current can flow through the photoelement.

The series circuit has a high resistance value if the conduction layer is separated into two electrically insulated parts, one of which is connected to the first terminal and the other of which is connected to the second terminal of the fuse. The fuse is programmed in this case. The conduction layer is interrupted and, consequently, no current can flow through the fuse.

The series circuit has a low resistance value if a part of the photosensor region is uncovered, the conduction layer extends from the first terminal to the second terminal of the fuse, and a light bundle enters into the photosensor region. The fuse is incorrectly programmed in this case. The conduction layer of the fuse is not interrupted. Moreover, the photosensor region is partly uncovered. Therefore, current can flow both through the photoelement and through the fuse and, consequently, through the series circuit.

The low resistance value of the series circuit when a fuse is incorrectly programmed is dependent on an intensity of the light bundle, while the high resistance value of the series circuit when a fuse is unprogrammed, and the high resistance value of the series circuit when a fuse is programmed, are independent of the intensity of the light bundle.

If the semiconductor circuit contains an incorrectly programmed fuse, light can enter into a region of the photosensor region that is not covered by the metal bridge. A temporal variation of the intensity of the light entering into the photosensor region, therefore, brings about a temporal variation of the conductivity. This can be observed.

In a preferred embodiment of the invention, an electrically insulating layer transmissive to the light bundle is preferably arranged between the conduction layer of the fuse and the photosensor region of the photoelement. The photosensor region is a semiconducting region, by way of example. The conduction layer is an electrically conductive region and arranged between the two is a dielectric, which is transmissive to the light used. Apart from visible light, it is also possible to use infrared or ultraviolet light as alternative embodiments.

The semiconductor circuit preferably comprises a first terminal contact for application of a supply voltage, a second terminal contact for application of a reference potential that is connected to the second terminal of the fuse, a resistance element having a first terminal connected to the first terminal of the photoelement, and a second terminal connected to the first terminal contact. Since the first terminal contact and the second terminal contact are provided for the power supply of the semiconductor circuit, a current flows via these terminal contacts during operation. If the series circuit comprising the photoelement and the fuse have a low resistance value, and the fuse is incorrectly programmed, an additional current flows between the first terminal contact and the second terminal contact. Therefore, at a predetermined operating voltage, the current consumption of the semiconductor circuit increases. Due to the use of the invention, this increase in the current consumption can be ascertained by means of a comparative measurement.

If the fuse is incorrectly programmed, then a current flows through the photoelement. The current flowing through the photoelement is only a part of the total current flowing between the first terminal contact and the second terminal contact. However, the current flowing through the photoelement is dependent on the conductivity of the photosensor region. The conductivity of the photosensor region is dependent on the intensity of the light bundle. Therefore, the total current is also dependent on the intensity of the light bundle. The dependence of the total current on the intensity of the light bundle can be ascertained by measuring at least two current intensities, which are assigned to different intensity values of the light bundle.

The resistance element preferably comprises a series circuit formed by a first resistance element and a second resistance element, each having a first terminal and a second terminal. The semiconductor circuit then preferably comprises a third terminal contact connected to the first terminal of the photoelement and the first terminal of the first resistance element, a fourth terminal contact connected to the second terminal of the first resistance element and to the first terminal of the second resistance element. If the series circuit formed by the photoelement and the fuse has a low resistance value, the fuse is incorrectly programmed, and a voltage difference can be measured between the third terminal contact and the fourth terminal contact. If the resistance value of the first resistance element is known, it is possible to determine a current intensity of the current flowing through the photoelement. It can at least be determined whether an appreciable current is actually flowing through the photoelement, that is to say, it can be determined whether the fuse is incorrectly programmed.

In another preferred embodiment of the invention, the semiconductor circuit may also only comprise a third terminal contact connected to the first terminal of the photoelement. The first terminal of the photoelement is then connected exclusively to the third terminal contact. If a voltage is applied between the third terminal contact and the second terminal contact, and the fuse is incorrectly programmed, current flowing between the third terminal contact and the second terminal contact can be measured. The resistance of the series circuit comprising the photoelement and fuse can be determined from the applied voltage and the measured current. The current measured between the third terminal contact and the second terminal contact is the current flowing through the photoelement.

In another preferred embodiment of the invention, the semiconductor circuit preferably comprises a read-out circuit connected to the fuse. The read-out circuit then comprises a first control input and a second control input, a first transistor having a control terminal connected to the first control input and a controlled path, a second transistor having a control terminal connected to the second control input and a controlled path, a latch having an input and an output with the input of the latch being connected to the first terminal contact via the controlled path of the first transistor and to the first terminal of the fuse via the controlled path of the second transistor. The application of the supply voltage to the first terminal contact and the second terminal contact then triggers a read-out of the fuse by the read-out circuit, and a generation of a voltage level assigned to the programming state of the fuse at the output of the read-out circuit. If the fuse is unprogrammed, a first voltage level is generated. If the fuse is programmed, a second voltage level is generated.

The latch preferably comprises a first inverter and a second inverter, each having an input and an output. The input of the first inverter is connected to the input of the latch. The input of the second inverter is connected to the output of the first inverter. The output of the second inverter is connected to the output of the latch. The output of the second inverter is fed back to the input of the first inverter. When the supply voltage is applied, an initial level dependent on the programming state of the fuse forms at the input of the first inverter. Depending on the input level applied to the input of the first inverter, a first or second voltage level forms at the output of the second inverter. Since the output of the second inverter is fed back to the input of the first inverter, the first or second voltage level generated at the output of the second inverter remains stable.

An arrangement according to another embodiment of the invention for monitoring fuses of a semiconductor circuit comprises a semiconductor circuit including fuses, which may be programmed by impressing energy, photoelements with photosensors arranged below the conductive layers of the fuses, an illumination device for generating a light bundle that falls onto the semiconductor circuit, and a measuring device connected to the semiconductor circuit and having two terminals. The measuring device is designed for measuring a current flowing via the two terminals or for measuring a voltage difference applied between the two terminals.

In a first variant of a preferred method of the invention, the measuring device is designed to generate a voltage between the two terminals and to measure the current brought about by said voltage. One of the two terminals of the measuring device is connected to the first terminal of the photoelement. The other of the two terminals of the measuring device is connected to the second terminal of the fuse. The second terminal of the photoelement and the first terminal of the fuse are conductively connected to one another. The current flowing between the terminals of the measuring device is, therefore, dependent on the voltage generated between the terminals of the measuring device and the resistance of the series circuit formed by the photoelement and the fuse.

In a second variant of a preferred method to the invention, the measuring device is designed to measure a voltage difference prevailing between the two terminals. The arrangement comprises a resistance element having a first terminal connected to the first terminal of the photoelement and a second terminal. One of the two terminals of the measuring device is connected to the second terminal of the resistance element. The voltage difference measured between the two terminals of the measuring device is dependent on the resistance value of the resistance element and on a current flowing through the photoelement.

In a third variant of a preferred method of the invention, the measuring device is designed to measure a current flowing between the two terminals. The arrangement comprises a resistance element having a first terminal and a second terminal. One of the two terminals of the measuring device is connected to the first terminal of the resistance element. The second terminal of the resistance element is connected to the first terminal of the photoelement. A supply voltage can be applied to the other of the two terminals of the measuring device. A reference potential can be applied to the second terminal of the fuse. The current flowing between the terminals of the measuring device is the total current taken up by the semiconductor circuit. The light bundle, which falls onto the semiconductor circuit, preferably has an intensity. If the fuse is incorrectly programmed, the current flowing between the terminals of the measuring device is dependent on the intensity of the light bundle.

In a preferred embodiment, the illumination device preferably comprises a light source for generating a light beam and an interrupting device for repeatedly interrupting the light beam with an interruption frequency. The repeated interruption of the light beam generates a light bundle having a temporally variable intensity.

The arrangement of this embodiment preferably comprises a lock-in amplifier for generating a periodic signal with a predetermined frequency and for detecting the predetermined frequency in a measurement signal. The interrupting device is connected to the lock-in amplifier. The interruption frequency is defined by the predetermined frequency. The lock-in amplifier is connected to the measuring device. The measurement signal is defined by the total current measured by the measuring device.

A method according to the invention for monitoring fuses of a semiconductor circuit comprises a plurality of steps. A semiconductor circuit, having a fuse with a conduction layer and a photoelement with a photosensor region, is provided. The conduction layer of the fuse completely or partly covers the photosensor region of the photoelement. The conduction layer is illuminated with a light bundle. A current flowing through a series circuit formed by the photoelement and the fuse is determined. If a current flows through the series circuit, the fuse is incorrectly programmed.

In a first preferred alternative method, a voltage is impressed on the series circuit in order to generate the current. A resistance value of the series circuit is determined from the voltage and the current. The resistance values that result when an unprogrammed fuse or a programmed fuse is present should be known in this case. A deviation of the resistance value determined from the voltage and the current from said resistance values can then be ascertained.

In a second preferred alternative method, a current flowing through a series circuit formed by the fuse and the photoelement and a resistance element connected upstream and having a predetermined resistance value is generated. The voltage difference present at the resistance element is measured. The current intensity of the current is determined from the resistance element and the resistance value. In this case, the current flowing through the photoelement can be generated by a voltage that is not known precisely, since said current is measured directly.

In a third preferred alternative method, the intensity of the light bundle is varied. A current taken up by the semiconductor circuit is measured. A dependence between a value of the intensity and an intensity of the measured current is determined.

In another alternative method of the invention, the intensity can be varied by generating a light beam having a predetermined intensity and repeatedly interrupting it. The light bundle, which falls onto the semiconductor circuit, then has a first intensity in first time segments and a second intensity in second time segments.

In another alternative method of the invention, the dependence between the intensity and the current can be determined by determining a first current intensity while the light beam is interrupted, determining a second current intensity while the light beam is not interrupted, and comparing the first current intensity with the second current intensity.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1A shows a prior art read-out circuit for reading a fuse;

FIG. 1B shows the temporal development of the supply voltage and of the control voltages of the prior art read-out circuit according to FIG. 1A;

FIG. 2A shows three examples, (I) to (III), for fuses after the programming of a semiconductor circuit by a laser;

FIG. 2B shows the arrangement of a fuse and a photoelement, which is present in a semiconductor circuit according to the invention;

FIG. 2C shows a circuit diagram of the arrangement of a fuse and a photoelement according to FIG. 2B;

FIGS. 2D and 2E in each case show the arrangement of the fuse and the photoelement in accordance with FIG. 2B, the photoelement being further refined;

FIG. 3A shows a configuration of the semiconductor circuit according to the invention; and

FIG. 3B shows a configuration of the arrangement for the electro-optical monitoring of fuses of a semiconductor circuit according to the present invention.

The following list of reference symbols can be used in conjunction with the figures:

| | |
|---|---|
| 1 | Semiconductor circuit |
| 11 | Fuse |
| 111 | First terminal of the fuse |
| 112 | Second terminal of the fuse |
| 113 | Conduction layer of the fuse |
| 114 | Fusible region of the fuse |
| L | Length of the fusible region |
| B | Width of the fusible region |
| 1143 | First zone of the fusible region |
| 1144 | Second zone of the fusible region |
| A, B, C | Parts of the conduction layer |
| 12 | Photoelement |
| 121 | First terminal of the photoelement |
| 122 | Second terminal of the photoelement |
| 123 | Photosensor region of the photoelement |
| 13 | Light bundle |
| S | Intensity of the light bundle |
| t | Time |
| 14 | Series circuit comprising photoelement and fuse |
| R | Resistance of a fuse |
| RR | Rotation of a wheel |
| 15 | Transparent insulating layer |
| 16 | Read-out circuit |
| 161 | Output of the read-out circuit |
| V₁ | First voltage level of the output |
| V₂ | Second voltage level of the output |
| 101 | First terminal contact |
| V_{CC} | Supply voltage at the first terminal contact |
| 102 | Second terminal contact |
| V_{SS} | Reference potential at the second terminal contact |
| 162 | First control input of the read-out circuit |
| 163 | Second control input of the read-out circuit |
| U₁ | Bias voltage at the first control input |
| U₂ | Voltage pulse at the second control input |
| 103 | Third terminal contact |
| 104 | Fourth terminal contact |
| 17 | Resistance element |
| 171 | First terminal of the resistance element |
| 172 | Second terminal of the resistance element |
| 21, 22 | Illumination device |
| 23 | First measuring device |
| U, ΔU | Voltage between the two terminal contacts |
| I | Current between the two terminal contacts |
| 24 | Lock-in amplifier |
| 21 | Light source |
| 211 | Light beam |
| 22 | Interrupting device |
| f | Frequency |
| I | Total current |
| I₁ | Current flowing past the photoelement |
| I₂ | Current flowing through the photoelement |

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

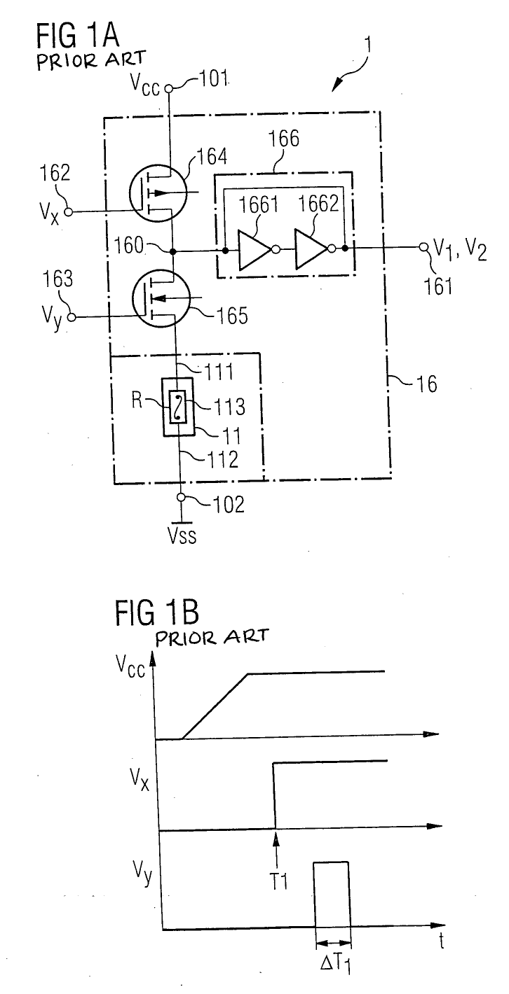

FIG. 1A illustrates a read-out circuit for reading a fuse. The illustrated detail from the circuit is known from the prior art.

The read-out circuit 16 has the first terminal contact 101 for the application of the supply voltage V_{CC}, the second terminal contact 102 for the application of a reference potential V_{SS}, and the output 161 for generating the first voltage level V₁ or the second voltage level V₂. The read-out circuit 16, furthermore, has the control terminals 162 and 163 for the application of the control voltages V_{X} and V_{Y}. The read-out circuit 16 additionally comprises the latch 166, the p-channel field effect transistor 164 and the n-channel field effect transistor 165.

The fuse 11 has the first terminal 111 and the second terminal 112. The fuse 11 contains a conduction layer 113 connected to the first and second terminals 111 and 112. The conduction layer 113 is effective as a resistance element. The resistance value between the first and second terminals of the fuse 11 can be programmed by impressing energy. By impressing energy, the conductive connection between the terminals 111 and 112 is interrupted by means of the conduction layer 113 being fused or vaporized for example by mometary irradiation with a laser beam.

The latch 166 has an input and an output. The latch 166 comprises the inverters 1661 and 1662, each having an input and an output. The input of the inverter 1661 is connected to the input of the latch. The output of the inverter 1661 is connected to the input of the inverter 1662. The output of the inverter 1662 is connected to the output of the latch 166 and to the input of the inverter 1661. The output of the latch 166 is connected to the output of the read-out circuit 16.

The field effect transistors 164 and 165 each have a controlled path and a control terminal. The controlled paths each have a first and a second terminal. The first terminal of the controlled path of the p-channel field effect transistor 164 is connected to the terminal contact 101. The second terminal of the controlled path of the p-channel field effect transistor 164 is connected to the first terminal of the controlled path of the n-channel field effect transistor 165. The second terminal of the controlled path of the n-channel field effect transistor 165 is connected to the first terminal of the fuse 11. The second terminal of the fuse 11 is connected to the second terminal contact 102. The second terminal of the controlled path of the p-channel field effect transistor 164 and the first terminal of the controlled path of the n-channel field effect transistor 165 are connected to the input of the latch 166. The control terminal of the p-channel field effect transistor 164 is connected to the control input 162 of the read-out circuit 16. The control terminal of the n-channel field-effect transistor 165 is connected to the control input 163 of the read-out circuit 16.

FIG. 1B illustrates the temporal profile of the supply voltage and of the control voltages as occur in the operation of the circuit according to FIG. 1A. First, a semiconductor circuit is connected to a reference potential V_{SS} and to an external supply voltage. During the switch-on operation, the supply voltage V_{CC} at the first terminal contact 101 rises to a defined value. Moreover, the reference potential V_{SS} is applied to the second terminal contact 102. The control voltage V_{X} present at the first control input 162 of the read-out circuit 16 is raised to a first high level at the instant T₁. A bias voltage is thus applied to the first control input 162. The control voltage V_{Y} present at the second control input 163 of the read-out circuit 16 is then raised to a second level for the time period ΔT₁. A voltage pulse is thus applied to the second control input 163. The voltage present at the input of the latch 166 for the time period ΔT₁ depends on the resistance value R of the fuse 11. If the conduction layer 113 of the fuse 11 is interrupted, the latch 166 generates the first voltage level V₁ of its output 161, for example the supply voltage V_{CC}. If the conduction layer 113 of the fuse 11 covers the entire fusible region 114, the latch 166 generates the second voltage level V₂, for example the reference potential V_{SS}, at its output 161. Since the output of the inverter 1162 is fed back to the input of the inverter 1161, the first voltage level V₁ or the second voltage level V₂ established in the course of the time period ΔT₁ at the output 161 of the read-out circuit 16 also remains stored in the later 166 after the time period ΔT₁ has elapsed.

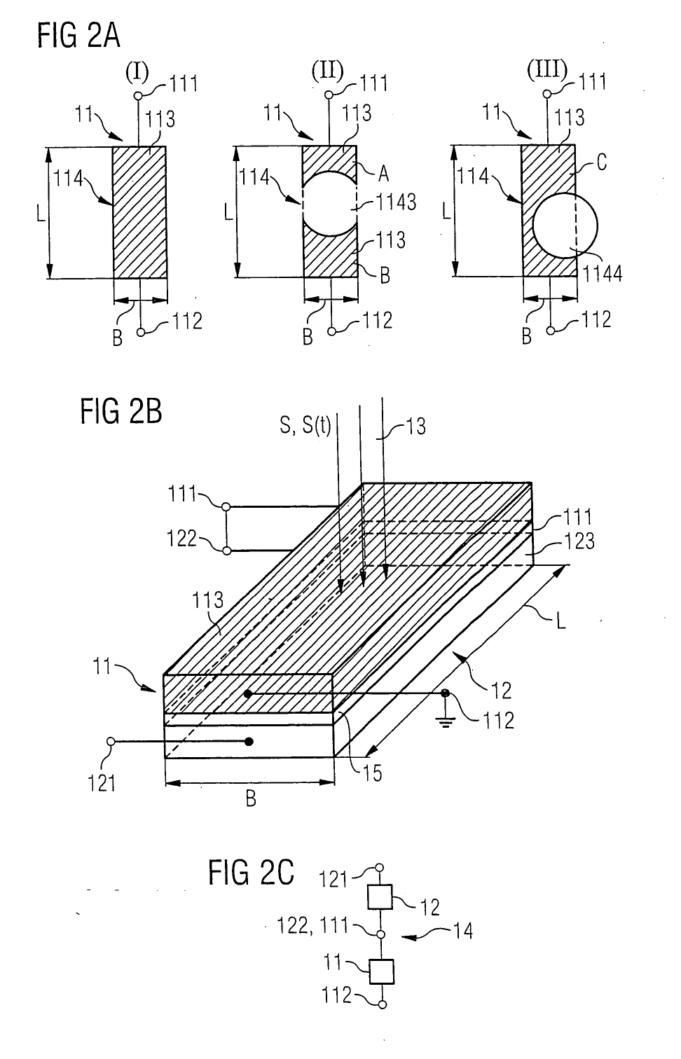

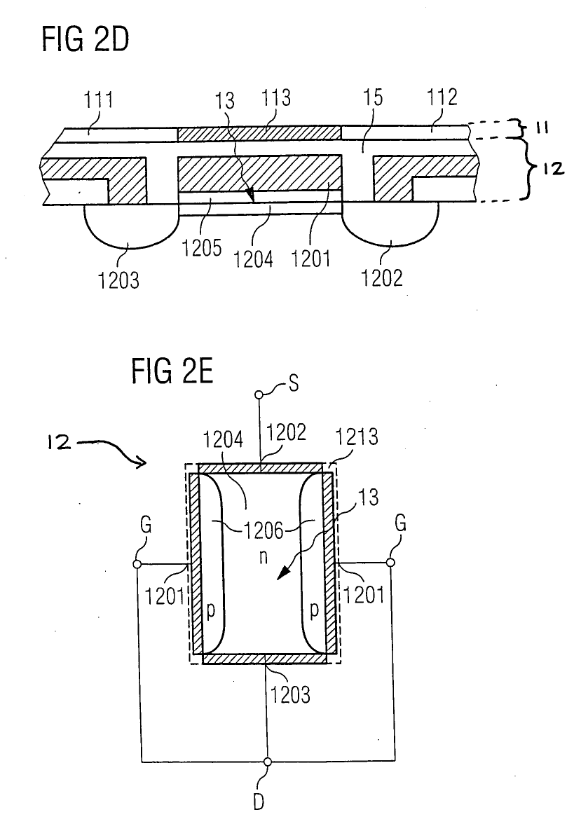

FIG. 2A illustrates three examples, (I) to (III), for fuses after the programming of a semiconductor circuit by a laser.

In each of the examples, (I) to (III), the fuse 11 in each case has a first terminal 111 and a second terminal 112 and comprises a fusible region 114. The fusible region has, for example, a rectangular form with a length L and a width B, the length L preferably being greater than the width B. A conduction layer 113 is arranged in the fusible region 114. The first terminal 111 and the second terminal 112 are connected to the conduction layer 113 at the edges of the width B of the fusible region 114. The conduction layer 113 produces an electrically conductive connection between the two terminals, which can be interrupted by supplying heat. The conduction layer 113 may be, for example, a metal or an alloy having a low melting point. Known materials for the conduction layer 113 are known from the prior art. The conductive connection may be interrupted, for example, by bombardment with a laser beam.

The example (I) in FIG. 2A illustrates an unprogrammed fuse 11, in which, the conduction layer 113 completely covers the fusible region 114. The conductive layer 113 extends over the entire fusible region 114.

The example (II) of FIG. 2A illustrates a programmed fuse 11, the conduction layer 113 of which is removed after programming in a first zone 1143. The first zone 1143 separates the conduction layer 113 into two parts A and B: the part A is electrically conductively connected to the first terminal 111 and the part B is electrically conductively connected to the second terminal 112 of the fuse 11. However, the two parts, A and B, are electrically insulated from one another. The electrical contact between the first terminal 111 and the second terminal 112 of the fuse 11 is, therefore, interrupted.

The example (III) of FIG. 2A illustrates an incorrectly programmed fuse 11, in which the conduction layer 113 is removed after programming in a second zone 1144. However, in this example, the second zone 1144 does not separate the conduction layer 113 into two different parts that are electrically insulated from one another. Rather, the remaining part C of the conduction layer 113 is connected to the first terminal 111 and to the second terminal 112 of the fuse 11. The electrical contact between the first terminal 111 and the second terminal 112 of the fuse 11 is, therefore, not interrupted.

FIG. 2B illustrates an arrangement of a fuse and a photoelement, such as is present in a semiconductor circuit according to the invention. The arrangement comprises the fuse 11 and the photoelement 12. The fuse 11 has the first terminal 111 and the second terminal 112. The photoelement 12 has the first terminal 121 and the second terminal 122. The second terminal 122 of the photoelement 12 and the first terminal 111 of the fuse 11 are electrically conductively connected to one another. The semiconductor circuit, thus, comprises a series circuit 14 formed by the fuse 11 and the photoelement 12. In the series circuit, the second terminal 122 of the photoelement 12 is connected to the first terminal 111 of the fuse.

The fuse 11 has the conduction layer 113 arranged in a fusible region 114. The fusible region 114 has, for example, the form of a rectangle in plan view and has the length L and the width B. Prior to programming, the conduction layer 113 covers the entire fusible region 114, as illustrated with reference to the example (I) of FIG. 2A. During the programming of the semiconductor circuit, the conduction layer 113 is at least partly removed from a zone of the fusible region 114. After the programming of the semiconductor circuit, the conduction layer 113 may be arranged in the fusible region in the manner illustrated with reference to the examples (II) and (III) of FIG. 2A.

The photoelement 12 comprises the photosensor region 123. The photosensor region 123 of the photoelement 12 has an electrical conductivity that can be varied by light radiated in. In particular, the electrical conductivity of the photosensor region 123 depends on the intensity of the light radiated in. The photoelement 12 is, for example, a semiconductor component having a junction zone between p-conducting and n-conducting regions. A deficiency of free charge carriers and a strong electric field form in the junction zone. Pairs of free charge carriers, which arise as a result of photons radiated in, are separated by the field and bring about a photocurrent.

The photoelement 12 and the fuse 11 are formed relative to the direction of the incident light bundle 13, and arranged with respect to one another in such a way that the conduction layer 113 of an unprogrammed fuse 11 covers the entire fusible region 114 and, thus, the entire photosensor region 123 of the photoelement 12. An in programmed fuse conductive layer 113, thus, prevents light from being able to enter into the photosensor region 123. In the case of a programmed or incorrectly programmed fuse, by contrast, light can enter into the photosensor region 123 since the conduction layer 113 of the fuse 11 is, in each case, removed from a zone of the fusible region 114.

FIG. 2C illustrates a circuit diagram of the arrangement of a fuse and a photoelement as illustrated in FIG. 2B. The arrangement comprises a series circuit 14 formed by the photoelement 12 and the fuse 11. The second terminal 122 of the photoelement 12 is connected to the first terminal 111 of the fuse. The resistance of the series circuit measured between the first terminal 121 of the photoelement 12 and the second terminal 112 of the fuse 11 has the first value R1, the second value R2 or the third value R3, depending on the arrangement of the conduction layer 113 in the fusible region 114. The resistance of the series circuit has the first value R1 if the conduction layer 113 is arranged in the fusible region 114 of the fuse 11, as described with reference to the example (I) of FIG. 2A, that is to say, the conduction layer 113 extends over the entire fusible region 114 of the fuse 11. The resistance of the series circuit has the second value R2 if the conduction layer 113 is arranged in the fusible region 114 of the fuse 11, as described with reference to the example (II) of FIG. 2A, that is to say, the electrical contact between the first terminal 111 and the second terminal 112 of the fuse 11 is interrupted. The resistance of the series circuit has the third value R3 if the conduction layer 113 is arranged in the fusible region 114 of the fuse 11, as described with reference to the example (III) of FIG. 2A, that is to say, the conduction layer 113 is partly removed from the fusible region 114, but the electrical contact between the first terminal 111 and the second terminal 112 of the fuse 11 is not interrupted. The first value R1 is relatively high and independent of the intensity S of the light bundle 13, because the conduction layer 113 of the fuse 11 completely shades the photosensor region 123 of the photoelement 12 from the light bundle 13 and the photoelement 12, therefore, has a high photoresistance. The second value R2 is relatively high and independent of the intensity S of the light bundle 13, because the conduction layer 113 is interrupted between the first terminal 111 and the second terminal 112 of the fuse 11 and, therefore, no current can flow through the series circuit 14. By contrast, the third value R3 is relatively low and dependent on the intensity S of the light bundle 13, because a part of the light bundle 13 can enter into the photosensor region 123 of the photoelement 12 and the conduction layer 113 is not interrupted between the first terminal 111 and the second terminal 112 of the fuse 11.

If the conduction layer 113 is arranged in the fusible region 114 of the fuse 11 in the manner described with reference to the examples (I) and (II) of FIG. 2A, the series circuit 14, therefore, has a relatively high resistance value R1 or R2 independent of the intensity S of the light bundle 13. If the conduction layer 113 is arranged in the fusible region 114 of the fuse 11 in the manner described with reference to the example (III) of FIG. 2A, the series circuit 14 has a relatively low resistance value R3 dependent on the intensity S of the light bundle 13.

The series circuit 14 thus has a high resistance value if the fuse 11 is unprogrammed or programmed. The series circuit 14 has a low resistance value if the fuse 11 is incorrectly programmed.

FIGS. 2D and 2E illustrate an embodiment of the arrangement of the fuse 11 and the photoelement 12 in accordance with FIG. 2B. In both figures, the photoelement 12 is a field effect transistor having a source-drain channel 1204. The conduction layer 113 of the fuse 11 is, in each case, arranged above the source-drain channel 1204 of the field effect transistor 120. If the fuse 11 is unprogrammed, then the conduction layer 113 completely covers the source-drain channel 1204. Consequently, the light bundle 13 cannot enter into the source-drain channel 1204 in order to generate mobile charge carriers. If the fuse 11 is programmed or incorrectly programmed, the conduction layer 113 is partly removed from the source-drain channel 1204. Consequently, the light bundle 13 can enter into the now uncovered part of the source-drain channel 1204 in order to generate mobile charge carriers. The photoelement 12 is connected in series with the fuse 11. A current can flow through the series circuit 14 formed by the photoelement 12 and the fuse 11 only when the light bundle 13 enters into the source-drain channel 1204 and the fuse 11 is incorrectly programmed.

The photoelement 12 illustrated in FIG. 2D is a MOS field effect transistor. The transistor comprises a heavily n-doped source zone 1202, a heavily n-doped drain zone 1203 and a likewise heavily n-doped source-drain channel 1204, which are arranged in a semiconducting weakly p-doped substrate. The transistor, furthermore, comprises a gate electrode 1201, which is electrically insulated from the semiconducting substrate by an oxide layer 1205. The source-drain channel 1204 is so thin that it is depleted of mobile charge carriers when the substrate and the gate electrode 1201 are at reference potential V_{SS}. However, mobile charge carriers can be generated in the source-drain channel 1204 by radiating in photons; said mobile charge carriers leading to a photocurrent between the source zone 1202 and the drain zone 1203 when a voltage is present between the source zone 1202 and the drain zone 1203. Given a suitable interconnection of the phototransistor, the potential of the gate electrode 1201 can be raised by the photocurrent, as a result, the number of mobile charge carriers in the source-drain channel 1204 rises further on account of the field effect.

The photoelement 12 illustrated in FIG. 2E is a junction field effect phototransistor. The n-conducting source-drain channel 1204 is surrounded by the p-conducting zones 1206 and depleted of mobile charge carriers. However, mobile charge carriers can be generated in the source-drain channel 1204 by radiating in photons, said mobile charge carriers leading to a photocurrent when a voltage is present between the source electrode 1202 and the drain zone 1203. Given a suitable interconnection of the phototransistor, the potential of the gate electrode 1201 can be raised by the photocurrent, as a result of which, the number of mobile charge carriers in the source-drain channel 1204 rises further on account of the field effect.

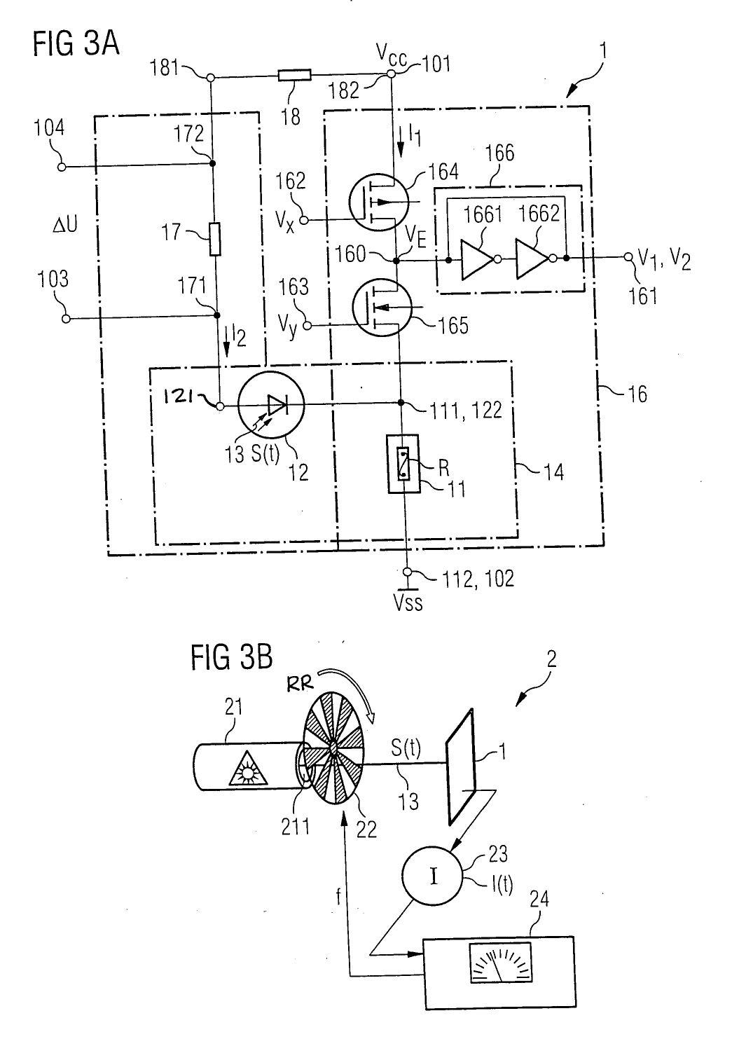

FIG. 3A illustrates a preferred embodiment of the semiconductor circuit according to the invention. The semiconductor circuit 1 comprises a fuse 11 and a photoelement 12 arranged and connected up in the manner described with reference to FIGS. 2B and 2C. The fuse 11 has the first terminal 111 and the second terminal 112. The photoelement 12 has the first terminal 121 and the second terminal 122. The second terminal 122 of the photoelement 12 is conductively connected to the first terminal 111 of the fuse 11.

The semiconductor circuit 1, furthermore, comprises the read-out circuit 16. The read-out circuits 16 illustrated in FIGS. 1A and 3A have the same construction and the same functioning. However, the read-out circuit 16 of FIG. 3A is connected to a fuse 11, the conduction layer of which is physically arranged above the photosensor region of a photoelement 12.

The programming of a semiconductor circuit comprises the programming of selected fuses of the semiconductor circuit. The selected fuses are then either programmed or incorrectly programmed. The rest of the fuses remain unprogrammed. After the programming of the semiconductor circuit, a fuse 11 is either unprogrammed, programmed, or incorrectly programmed. The series circuit 14, accordingly, has one of three resistance values between the first terminal 121 of the photoelement 12 and the second terminal 112 of the fuse 11.

If the fuse 11 is unprogrammed or programmed, the series circuit 14 has a relatively high resistance value R1 or R2. By contrast, if the fuse 11 is incorrectly programmed, the series circuit 14 has a relatively low resistance value R3. The resistance value of the series circuit 14 can be determined in various ways.

The semiconductor circuit 1 has a first terminal contact 101 for the application of a supply voltage V_{CC} and a second terminal contact 102 for application of a reference potential V_{SS}. The second terminal 112 of the fuse 11 is connected to the second terminal contact 102. In order to ascertain the resistance of the series circuit 14, the semiconductor circuit 1 may be formed with further terminal contacts.

In a preferred embodiment, the semiconductor circuit may have, for example, a third terminal contact 103 connected to the first terminal 121 of the photoelement 12. The current I₂ flowing through the series circuit 14 can then be determined by applying a voltage U between the third terminal contact 103 and the second terminal contact 102 and directly measuring the current I₂ flowing between the third terminal contact 103 and the second terminal contact 102. A current I₂ having an appreciable current intensity results only in the case in which the fuse 11 is incorrectly programmed, and the resistance of the series circuit 14 has the relatively low third value R3.

The impressing of the voltage and measuring of the current may be effected using a needle (probe) card, by way of example.

The semiconductor circuit may also have a third terminal contact 103, a fourth terminal contact 104 and a resistance element 17. The resistance element 17 has a first terminal 171 and a second terminal 172. The first terminal 171 of the resistance element 17 is connected to the third terminal contact 103. The second terminal 172 of the resistance element 17 is connected to the fourth terminal contact 104. If the resistance of the resistance element 17 is known, it is possible to determine the current through the series circuit 14 by measuring the voltage difference ΔU between the third terminal contact 103 and the fourth terminal contact 104. An appreciable voltage difference ΔU results only in the case in which the fuse 11 is incorrectly programmed, and the series circuit 14, therefore, has the relatively low resistance value R3. In this case, the fourth terminal contact 104 may be connected to the terminal contact 101 via a further resistance element 18 having a resistance that is not defined.

In a preferred embodiment, the first terminal 121 of the photoelement 12 is connected to the first terminal contact 101 via an unknown resistance, for example via the series circuit formed by the resistance elements 17 and 18. The total current I flowing between the first terminal contact 101 and the second terminal contact 102 is measured. The total current I is composed of the current I₂ flowing through the photoelement 12 and the current I₁ flowing through the rest of the semiconductor circuit 1. The two currents I₁ and I₂ can be separated if a suitable time profile I₂(t) is impressed on the current I₂.

FIG. 3B illustrates an embodiment of the arrangement according to another preferred embodiment of the invention for the electro-optical monitoring of fuses of a semiconductor circuit. The arrangement 2 comprises the light source 21, which is designed for generating the second light bundle 211 having constant intensity, and the interrupting device 22, which is arranged in the beam path of the second light bundle 211, and is designed for repeatedly interrupting the second light bundle 211.

The interrupting device 22 comprises, for example, a disk rotating with constant frequency f in the direction RR of rotation, and has radially extending perforations (chopper). The light bundle 13 can be generated by repeatedly interrupting the second light bundle 211. The intensity S of the light bundle 13 then has a time profile S(t).

The arrangement 2 additionally comprises the semiconductor circuit 1, arranged in the beam path of the light bundle 13 and described with reference to FIG. 3A, with the series circuit 14 formed by the fuse 11 and the photoelement 12, as described with reference to FIG. 2C, the measuring device 23, and the lock-in amplifier 24.

The measuring device 23 is designed for measuring a temporally variable current. The measuring device 23 is connected to the first terminal contact 101 and the second terminal contact 102 of the semiconductor circuit 1. Therefore, the total current I flowing between the first terminal contact 101 and the second terminal contact 102 can be measured via the measuring device 23. If a fuse 11 of the semiconductor circuit 1 is incorrectly programmed, the total current I comprises a current I₂ flowing through the photoelement 12 and having the time profile I₂(t), which is defined by the time profile S(t) of the intensity S of the light bundle 13. The total current I is, thus, temporally variable and has a time profile I(t).

The lock-in amplifier 24 is designed to generate an output signal in a manner dependent on an input signal and a reference signal, a time profile, for example, a harmonic oscillation being prescribed by the reference signal and the output signal being defined by the amplitude of a component of the input signal, which has said time profile. The reference signal may be generated by the lock-in amplifier 24 itself, or be fed in externally.

In an alternative preferred method of the invention, the lock-in amplifier 24 generates a reference signal having the frequency f. The reference signal is fed to the interrupting device 22. The frequency f of the reference signal defines a periodic time profile S(t) of the intensity S of the light bundle 13. The measuring device 23 generates an output signal defined by the time profile I(t) of the total current I taken up by the semiconductor circuit. The output signal generated by the measuring device 23 is fed as input signal to the lock-in amplifier 24

If even only one fuse 11 of the semiconductor circuit 1 is incorrectly programmed, the total current I contains a component, which is assigned to the current I₂ flowing through the photoelement 12. The time profile I₂(t) of the current I₂ is defined by the frequency f generated by the lock-in amplifier 24. The output signal generated by the lock-in amplifier 24 is thus defined by the amplitude of the current I₂.

In another preferred method of the invention, a light bundle 13 having a temporally variable intensity S is generated by means of the interrupting device 22. The time profile S(t) of the intensity S is measured, for example, by an additional photoelement (not shown) arranged within the light bundle 13 and is fed as reference signal to the lock-in amplifier 24.

In an alternative preferred embodiment, semiconductor circuit may comprise a multiplicity of fuses 11 and photoelements 12 arranged and connected up in the manner described with reference to FIGS. 2B and 2C. The first terminals 121 of the photoelements 12 may be connected to the first terminal contact 101 via a common bus line. If the intention is only to ascertain whether or not a semiconductor circuit contains an incorrectly programmed fuse 11, then it suffices for the conduction layers 113 of the fuses 11 to be illuminated jointly. If the intention is to ascertain which ones of the fuses 11 of the semiconductor circuit are incorrectly programmed, the conduction layers 113 of the respectively fuses 11 may, for example, be illuminated individually one after the other. Other arrangements are possible to illuminate groups or sections of the fuses 11.

Although the present invention and its advantages have been described in detail, it should be understood that various changes, substitutions and alterations can be made herein without departing from the spirit and scope of the invention as defined by the appended claims. For example, many of the features and functions discussed above can be implemented in software, hardware, or firmware, or a combination thereof. As another example, it will be readily understood by those skilled in the art that the term “programmed” and “unprogrammed” may be reversed and the measurements may be varied while remaining within the scope of the present invention.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor circuit, comprising:
a fuse having a first terminal, a second terminal and a conduction layer that is opaque to a light bundle and that can be fused by impressing energy; and
a photoelement having a first terminal, a second terminal, and a photosensor region which is sensitive to the light bundle;
the conduction layer of the fuse being arranged overlying the photosensor region of the photoelement.

2. The semiconductor circuit of claim 1, wherein the second terminal of the photoelement and the first terminal of the fuse are coupled to one another in order to form a series circuit comprising the photoelement and the fuse.

3. The semiconductor circuit of claim 2, wherein the series circuit has a high resistance value if the conduction layer covers the entire photosensor region.

4. The semiconductor circuit of claim 2, wherein the series circuit has a high resistance value if the conduction layer is separated into two electrically insulated parts, one of which is connected to the first terminal and the other of which is connected to the second terminal of the fuse.

5. The semiconductor circuit of claim 2, wherein the series circuit has a low resistance value if a part of the photosensor region is uncovered, the conduction layer extends from the first terminal to the second terminal of the fuse and a light bundle enters into the photosensor region.

6. The semiconductor circuit of claim 1, wherein an electrically insulating layer transmissive to the light bundle is arranged between the conduction layer and the photosensor region.

7. The semiconductor circuit of claim 1, comprising:
a first terminal contact for application of a supply voltage;
a second terminal contact for application of a reference potential coupled to the second terminal of the fuse; and
a resistance element having a first terminal connected to the first terminal of the photoelement and a second terminal connected to the first terminal contact.

8. The semiconductor circuit of claim 7, wherein the resistance element comprises a series circuit formed by a first resistance element and a second resistance element each having a first terminal and a second terminal, the semiconductor circuit further comprising:
a third terminal contact connected to the first terminal of the photoelement and the first terminal of the first resistance element; and
a fourth terminal contact connected to the second terminal of the first resistance element and to the first terminal of the second resistance element.

9. The semiconductor circuit of claim 7 further comprising a third terminal contact connected to the first terminal of the photoelement.

10. The semiconductor circuit of claim 7, further comprising:
a read-out circuit, which is connected to the fuse and which comprises:
a first control input and a second control input;
a first transistor having a control terminal connected to the first control input and a controlled path;
a second transistor having a control terminal connected to the second control input and a controlled path; and
a latch having an input and an output, the input of the latch being connected to the first terminal contact via the controlled path of the first transistor and to the first terminal of the fuse via the controlled path of the second transistor.

11. The semiconductor circuit of claim 10, wherein the latch contains a first inverter and a second inverter each having an input and an output, the input of the first inverter being connected to the input of the latch, the input of the second inverter being connected to the output of the first inverter, the output of the second inverter being connected to the output of the latch and the output of the second inverter being fed back to the input of the first inverter.

12. An arrangement for monitoring fuses of a semiconductor circuit, comprising:
a semiconductor circuit having:
at least one fuse with a first terminal, a second terminal, an a conduction layer that is opaque to a light bundle and that can be fused by the impressing energy, and
at least one corresponding photoelement having a first terminal, a second terminal, and a photosensor region, which is sensitive to the light bundle arranged beneath the conduction layer;
an illumination device for generating a light bundle that falls onto the semiconductor circuit; and
a measuring device connected to the semiconductor circuit and having two terminals, said measuring device being designed for measuring at least one of: a current flowing via the two terminals and a voltage difference between the two terminals.

13. The arrangement of claim 12, wherein the measuring device is designed to generate a voltage between the two terminals, one of the two terminals of the measuring device being connected to the first terminal of the photoelement, and the other of the two terminals of the measuring device being connected to the second terminal of the fuse.

14. The arrangement of claim 12, comprising a resistance element having a first terminal connected to the first terminal of the photoelement, and a second terminal, one of the two terminals of the measuring device being connected to the first terminal of the resistance element and the other of the two terminals of the measuring device being connected to the second terminal of the resistance element, the first terminal of the resistance element being connected to the first terminal of the photoelement and the voltage difference being dependent on a current flowing through the photoelement.

15. The arrangement of claim 12, comprising a resistance element having a first terminal and a second terminal, the first terminal of the resistance element being connected to the first terminal of the photoelement, the second terminal of the resistance element being connected to one of the two terminals of the measuring device, a supply voltage being able to be applied to the other of the two terminals of the measuring device and a reference potential being able to be applied to the second terminal of the fuse.

16. The arrangement of claim 15, wherein the illumination device comprises:
a light source for generating a light beam; and
an interrupting device, which is designed for repeatedly interrupting the light beam in order to generate the light bundle.

17. The arrangement of claim 16, comprising an amplifier for generating a periodic signal having a predetermined frequency and for detecting the frequency in a measurement signal, the amplifier being connected to the interrupting device, a repeated interruption of the light beam being defined by the frequency, the amplifier being connected to the measuring device, and the measurement signal being defined by the total current (I) taken up by the semiconductor circuit.

18. A method for monitoring fuses of a semiconductor circuit, comprising the steps of:
providing a semiconductor circuit having a photoelement with a photosensor region and a fuse with a conduction layer, the conduction layer of the fuse at least or partly covering the photosensor region of the photoelement;
illuminating the conduction layer and the photosensor region with a light bundle; and
determining a current flowing through a series circuit comprising the fuse and the photoelement.

19. The method of claim 18, and further comprising the step of:
impressing a voltage on the series circuit in order to generate the current; and
determining a resistance value of the series circuit from measurements of the voltage and the current.

20. The method of claim 18, and further comprising the steps of:
generating the current, which flows through the series circuit and through a resistance element connected upstream and having a predetermined resistance value;
measuring a voltage difference present at the resistance element; and
determining a current intensity of the current from the resistance value and the voltage difference.

21. The method of claim 18, and further comprising the steps of:
varying an intensity of the light bundle;
measuring a current intensity of the current taken up by the semiconductor circuit; and
determining a dependence between the intensity and the current intensity.

22. The method of claim 21, wherein the step of varying the intensity further comprises the step of periodically interrupting a light beam in order to effect the varying of the intensity of the light bundle.

23. The method of claim 22, wherein the step of determining the dependence between the intensity and the current intensity further comprises the steps of:
determining a first current intensity while the light beam is interrupted;
determining a second current intensity while the light beam is not interrupted; and
comparing the first current intensity and the second current intensity.
